(19) United States
(12) Patent Application Publication
(10) Pub. No.: US 2011/0261616 A1
(43) Pub. Date: Oct. 27, 2011

(54) WRITE SCHEME IN PHASE CHANGE MEMORY

(75) Inventor: Jin-Ki Kim, Ottawa (CA)

(73) Assignee: MOSAID TECHNOLOGIES INCORPORATED, Ottawa (CA)

(21) Appl. No.: 13/093,923

(22) Filed: Apr. 26, 2011

Related U.S. Application Data
(60) Provisional application No. 61/327,979, filed on Apr. 26, 2010.

(51) Int. Cl. G11C 11/00

(52) U.S. Cl. 365/163; 365/148

(57) ABSTRACT

A method for writing a phase change memory includes receiving an input data corresponding to a plurality of memory cells, while reading a previous data from the plurality of memory cells and comparing the input data with the previous data. Upon determining that the input data is different from the previous data for one or more of the plurality of memory cells, and upon determining that a current value of a write counter is less than a maximum value, one or more of the plurality of memory cells is programmed with the input data and the current value of the writer counter is incremented.

### CROSS-REFERENCE TO RELATED APPLICATIONS

This application is a utility application claiming priority to co-pending U.S. Provisional Application Ser. No. 61/327,979 filed on Apr. 26, 2010 entitled “WRITE SCHEME IN PHASE CHANGE MEMORY,” the entirety of which is incorporated by reference herein.

### TECHNICAL FIELD

The present invention relates generally to a semiconductor memory device. More specifically, the present invention relates to iterative verification of programmed data in a programmable semiconductor memory device.

### BACKGROUND

Phase change memories are nonvolatile memory devices storing data using phase change materials such as Chalcogenide. A common Chalcogenide compound is Ge₂—Sb₂—Te₅ (GST). These phase change materials are capable of stably transitioning between crystalline and amorphous phases by controlling heating and cooling processes. The amorphous phase exhibits a relatively high resistance compared to the crystalline phase, which exhibits a relatively low resistance. The amorphous state, also referred to as the RESET state or logic “0” state, is established by heating the GST compound above a melting temperature of 610° C., then rapidly cooling the compound. The crystalline state, also referred to as the SET state or logic “1” state is established by heating the GST compound above a crystallizing temperature of 450° C. but below the melting temperature of 610° C., and for a longer period of time sufficient to transform the material into the crystalline state, followed by a subsequent cooling period.

FIG. 1 shows a schematic of a typical phase change memory cell 10 comprising a storage element 12 and a switching element 14. The storage element is represented by a variable resistor whose value can be altered by transforming a structure between the crystalline and amorphous phases. The switching element 14 is used to selectively access the memory cell 10.

FIG. 2 shows a phase change memory cell storage element 20 with a heater 22 between a bottom electrode 24 and a Chalcogenide compound 26. The Chalcogenide compound 26 is contacted by a top electrode 28, typically with low resistance. Similarly, the bottom electrode 24 is used to make a low resistance contact to the heater 22. The heater 22 transforms a portion of the Chalcogenide compound 26 from the crystalline state to an amorphous state (shown) within a physical space referred to here as the programmable volume 29.

FIG. 3 is a graph showing the relationship of temperature versus time for both RESET and SET programming of a phase change memory as shown in FIG. 2. The phase change cell can be programmed to the amorphous or RESET state by heating the phase change layer to a temperature T_Reset with a current I_Reset through the heater for a duration equal to tP_Reset, then quickly cooling down the phase change layer. Similarly, the phase change cell can be programmed to the crystalline or SET state by heating the phase change layer to a temperature T_set with a current I_Set through the heater and maintaining the phase change layer at temperature T_Set for a duration equal to tP_Set, and then cooling down the phase change layer, where tP_Set exceeds tP_Reset. Also, shown are current pulses for writing RESET and SET states 32 and 34.

Phase change materials are thermally activated. The phase change memory cell is programmed to the SET state by applying a current I_Set for a duration equal to tP_Set. The amount of heat “J” applied to the phase change layer is proportional to I²×R, where “I” is a magnitude of a current I_Set through the heater and “R” is a resistance of the heater. While the memory cell is being programmed to the SET state, the phase change layer is changed to a crystalline state, resulting in a lower cell resistance compared to the RESET state as shown in FIGS. 4A and 4B. Similarly the phase change memory cell is programmed to the RESET state by applying a current I_Reset for a duration equal to tP_Reset. While the memory cell is being programmed to the RESET state, a certain volume of phase change layer is changed to the amorphous state, resulting in a higher cell resistance than the SET state. The programmable volume in a phase change layer is generally a function of “J”.

Phase change memory (PCM) devices typically use the amorphous state to represent a logical “0” state (or RESET state) and the crystalline state to represent a logical “1” state (or SET state). Table 1 summarizes typical phase change memory properties.

TABLE 1
Phase Change Memory Properties

| Data | “0” | “1” |
|---|---|---|
| Program State | Reset | Set |
| Resistance | High (>100K) | Low (10K) |
| Read Current | Low | High |
| Material Phase | Amorphous | Crystalline |
| Write Pulse | ~50 ns | ~200 ns |

FIG. 5 illustrates the distribution of PCM cell resistance for the SET state 52 and the RESET state 54. Specifically, the SET state has a resistance distribution spanning from values 56 and 58 (e.g. 10 Kohm). The RESET state has a resistance distribution spanning from two higher values 62 (e.g. 100 Kohm) and 64. The resistance values 58 and 62 are determined for a desired yield. For example, if the desired yield is 99%, then 1% of the programmed PCM cells could have a SET resistance higher than 58 or a RESET resistance lower than 62 and be deemed to have failed.

In recent years, various phase change memory cells have used an MOS transistor 74 shown in FIG. 6, a bipolar transistor 84 shown in FIG. 7 or a diode 94 shown in FIG. 8, as the switching element in the memory cell in an attempt to reduce cell size and thereby improve memory density. Further improvements in memory system density are needed to continue to reduce memory system cost and increase memory capacity driven in part by increased data traffic in electronic systems. Further improvements in memory bandwidth are also needed due in part to the higher memory data requirements of video medium.

### SUMMARY

In one aspect, the invention features a method for writing a phase memory comprising receiving an input data corresponding to a plurality of memory cells, while reading a previous data from the plurality of memory cells and comparing the input data with the previous data. Upon determining that the input data is different from the previous data for one of more of the plurality of memory cells, and upon determining that a current value of a write counter is less than a maximum value, the one or more of the plurality of memory cells is programmed with the input data and the current value of the write counter is incremented.

In another aspect, the invention features an apparatus for writing a phase change memory comprising a sense amplifier including a bias transistor and a differential voltage amplifier. The bias transistor is in communication with a positive input of a differential voltage amplifier. One of a plurality of memory cell is in communication with the positive input of the differential voltage amplifier. A sense voltage at the positive input of the differential voltage amplifier is in proportion to a bias resistance of the bias transistor and a memory cell resistance of the one of the plurality of memory cells. A reference voltage is in communication with a negative input of the differential voltage amplifier. The reference voltage is between the sense voltage obtained at the positive input of the differential voltage amplifier for the one of the plurality of memory cells in a SET state and the one of the plurality of memory cells in a RESET state. A register retains the state of a plurality of bits in a data-word. A write driver has a write current branch, a reset current branch and a set current branch. The reset current branch is enabled by a RESET state and disabled by the data-mask state. The set current branch is enabled by a SET state and disabled by the data-mask state. The write current branch mirrors a current of one of the reset current branch and the set current branch. An equivalence circuit sets the data-mask state corresponding to a bit in the data-word having the SET state when a corresponding sensed bit in the plurality of memory cells has the SET state, and sets the data-mask state corresponding to a bit in the data word having the RESET state when a corresponding sensed bit in the plurality of memory cells has the RESET state.

In another aspect, the invention features a phase change memory system comprising a memory array including a plurality of memory cells. Each of the plurality of memory cells is located at one of a plurality of rows and at one of a plurality of columns. Each local column selector of a plurality of local column selectors is in communication with a plurality of columns. A global column selector is in communication with the plurality of local column selectors. A sense amplifier is in communication with the global column selector. The sense amplifier includes a bias transistor and a differential voltage amplifier. The bias transistor is in communication with a positive input of a differential voltage amplifier. One of a plurality of memory cell is in communication with the positive input of the differential voltage amplifier. A sense voltage at the positive input of the differential voltage amplifier is in proportion to a bias resistance of the bias transistor and a memory cell resistance of the one of the plurality of memory cells. A reference voltage is in communication with a negative input of the differential voltage amplifier. The reference voltage is between the sense voltage obtained at the positive input of the differential voltage amplifier for the one of the plurality of memory cells in a SET state and the one of the plurality of memory cells in a RESET state. A register retains the state of a plurality of bits in a data-word. A write driver is in communication with the global column selector. A write driver has a write current branch, a reset current branch and a set current branch. The reset current branch is enabled by a RESET state and disabled by the data-mask state. The set current branch is enabled by a SET state and disabled by the data-mask state. The write current branch mirrors a current of one of the reset current branch and the set current branch. An equivalence circuit sets the data-mask state corresponding to a bit in the data-word having the SET state when a corresponding sensed bit in the plurality of memory cells has the SET state, and sets the data-mask state corresponding to a bit in the data-word having the RESET state when a corresponding sensed bit in the plurality of memory cells has the RESET state.

### BRIEF DESCRIPTION OF THE DRAWINGS

The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 is a schematic view of a phase change memory cell.

FIG. 2 is a cross-sectional view of a phase change memory cell storage element.

FIG. 3 is a graph of temperature change during a SET and a RESET operation of a conventional PCM cell.

FIG. 4A is a cross-sectional view of a phase change memory in the SET state.

FIG. 4B is a cross-sectional view of a phase change memory in the RESET state.

FIG. 5 is a graph of the resistance distribution for the SET and the RESET states.

FIG. 6 is a schematic view of an MOS transistor-based phase change memory cell.

FIG. 7 is a schematic view of a bipolar transistor-based phase change memory cell.

FIG. 8 is a cross-sectional view of a diode-based phase change memory cell.

FIG. 9 is a cross-sectional view of a diode-based phase change memory.

FIG. 10 is a timing diagram showing a single data rate (SDR) burst WRITE operation.

FIG. 11 is a timing diagram showing an SDR burst READ operation.

FIG. 12 is a graph of the resistance distribution for the SET and the RESET states in relation to reference resistances for the WRITE and the READ operations.

FIG. 13 is a flow chart of an example of a WRITE operation.

FIG. 14 is a schematic view of a phase change memory array.

FIG. 15 is a schematic view of a phase change memory WRITE operation.

FIG. 16 is a schematic view of a phase change memory READ operation.

FIG. 17 is a block diagram of a phase change memory bank architecture in accordance with an embodiment of the present invention.

FIG. 18 is a block diagram of a phase change memory architecture in accordance with an embodiment of the present invention.

FIG. 19 is a schematic view of a local column selector.

FIG. 20 is a schematic view of a global column selector.

FIG. 21 is a schematic view of a WRITE driver circuit.

FIG. 22 is a schematic view of a sense amplifier circuit.

FIG. 23 is a schematic view of a row decoder circuit.

FIG. 24 is a timing diagram for WRITE operation in accordance with an embodiment of the invention.

FIG. 25 is a timing diagram for READ operation in accordance with an embodiment of the invention.

FIG. 26 is a timing diagram of a WRITE operation.

FIG. 27 is a timing diagram of the WRITE operation showing SDR burst timing.

FIG. 28 is a timing diagram of a WRITE operation according to an embodiment of the present invention.

FIG. 29 is a timing diagram of the WRITE operation showing SDR burst timing.

FIG. 30 is a schematic view of an equivalence function performed in a WRITE driver and sense amplifier functional block according to an embodiment of the present invention.

FIG. 31 is a schematic view of an equivalence function performed in a register functional block according to an embodiment of the present invention.

FIG. 32 is logic diagram showing a WRITE masking operation performed by the equivalence function.

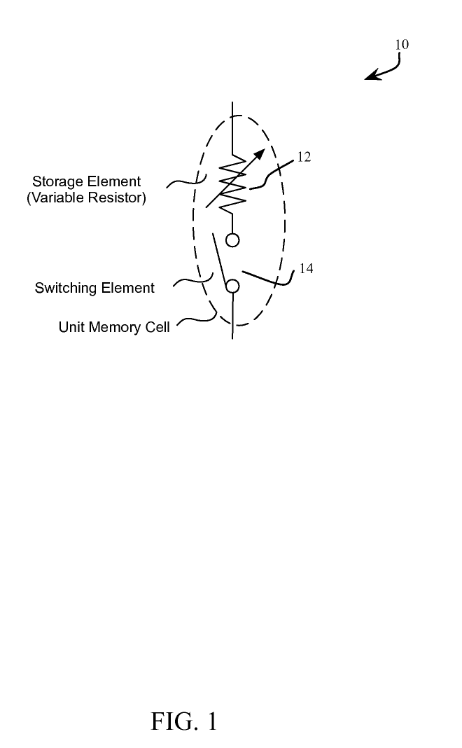

### DETAILED DESCRIPTION

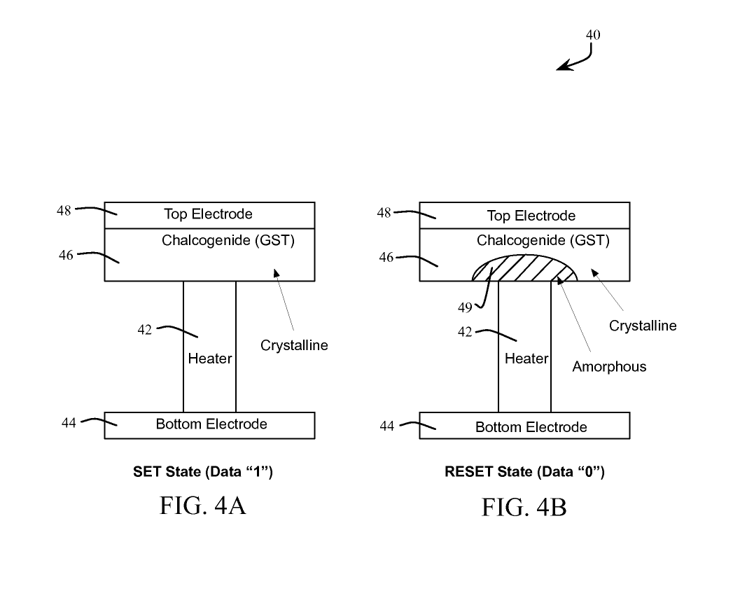

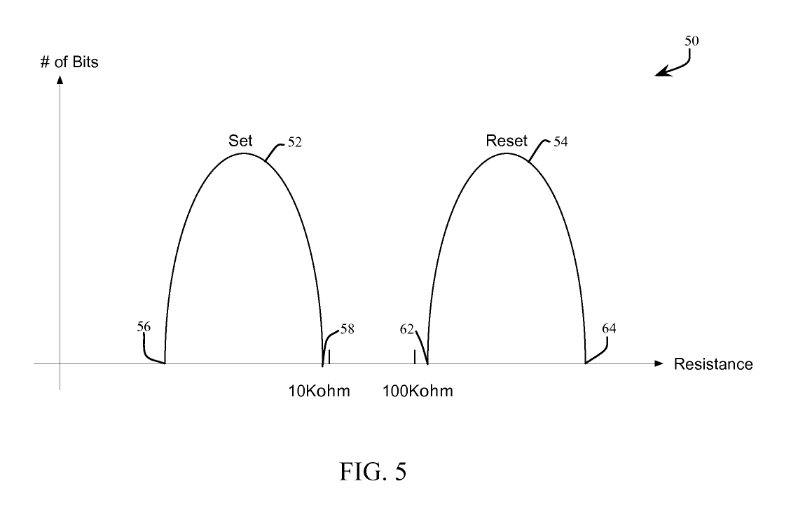

The memory cell distribution shown in FIG. 5 can be improved by decreasing the highest SET resistance 58, increasing the lowest RESET resistance 62, or both. This separates the two states further, which improves sensing margin. Improved sensing margin advantageously improves sensing reliability in the presence of noise as well as sensing speed. The resistance distributions of the SET and RESET states can be improved by reading a previously written memory cell and verifying that the state of the read cell matches what was previously written. This is referred to as a “write verify” or a “verification read” operation. If the read cell fails the write verify operation, the cell can be written again in an attempt to “correct” the memory bit. In one example, a bit fails because the amorphous region 49 in FIG. 4B is insufficiently formed or insufficiently removed through crystallization. The step of writing a memory cell is repeated for a fixed number of iterations, beyond which the memory is considered a permanent failed bit. In One example, a limit is set on the number of attempted write operations to screen out bits that have other latent failure mechanisms that could affect future reliability.

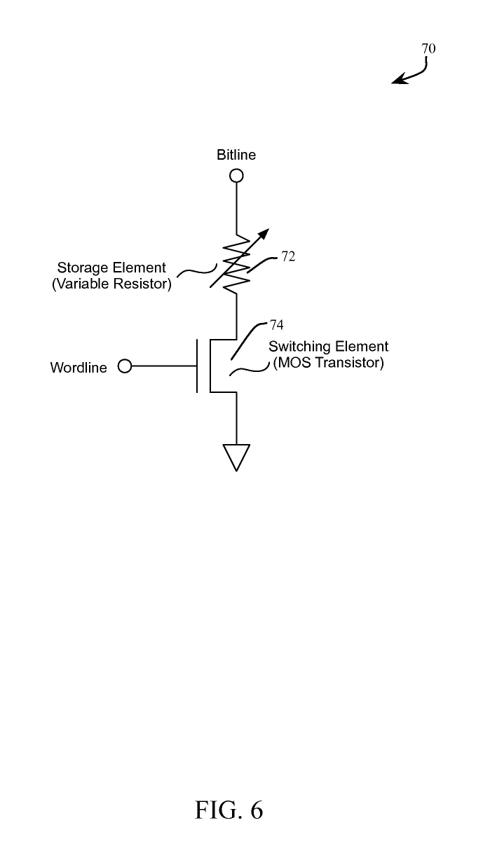

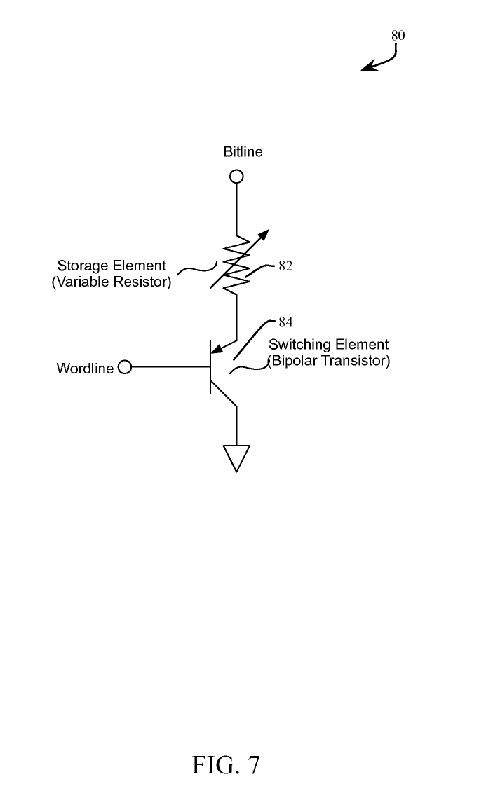

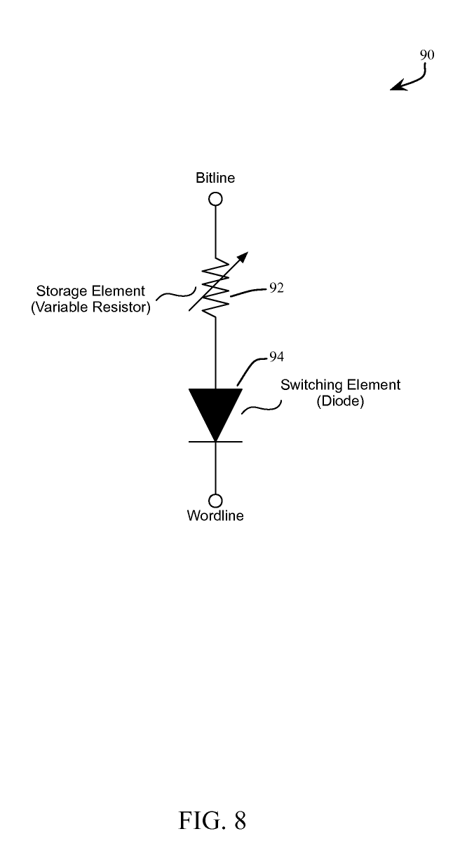

In one embodiment of the present invention, that write verify operation is performed during write data input. This advantageously improves write performance and tightly controls (e.g. reduces) the cell resistance distribution thereby reducing power consumption. For example, power consumption is reduced when sensing speed is increased, because bias transistors can be shut off sooner. One embodiment of the present invention is a diode-based PCM device with a memory cell as shown in FIG. 8, however other embodiments use either a FET based PCM memory cell as shown in FIG. 6 or a bipolar-based PCM memory cell as shown in FIG. 7.

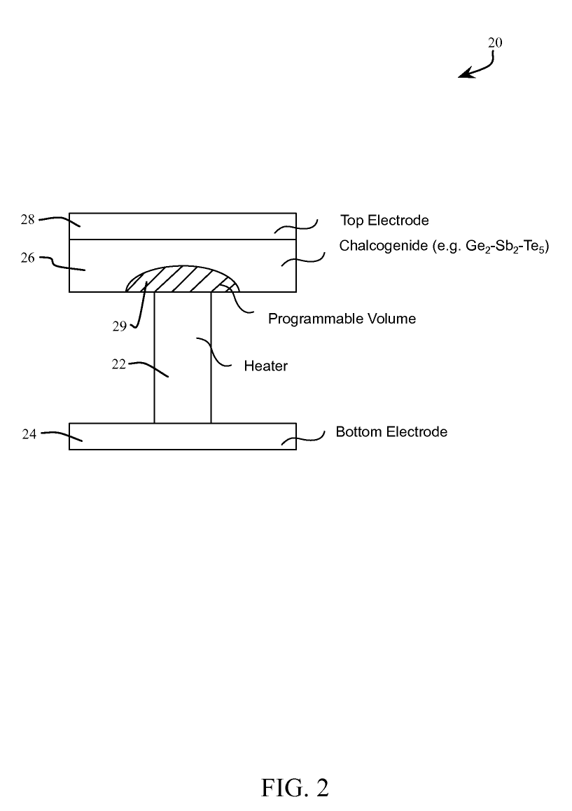

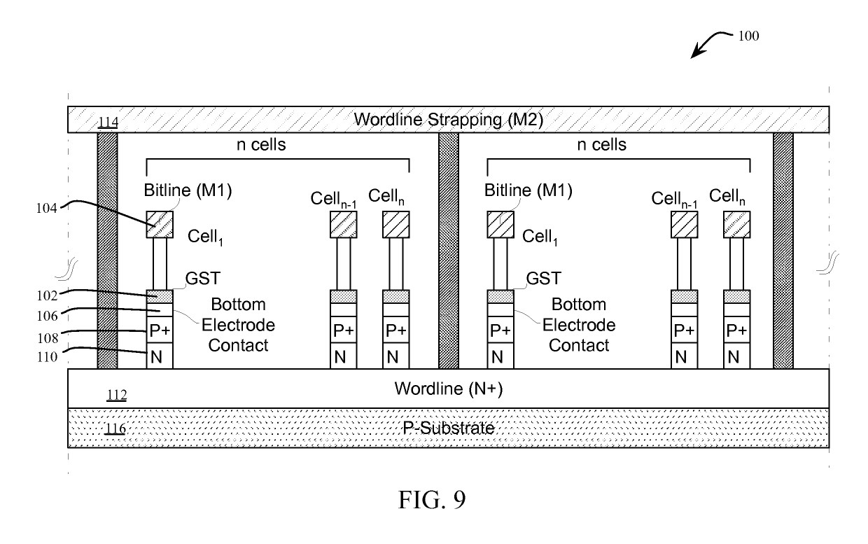

FIG. 9 shows a cross sectional view of a diode-based phase change memory according to an embodiment. Referring to FIG. 9, a top electrode 102 is connected to a bitline 104 formed by a first metal layer (M1). The bitline 104 communicates with circuitry (described below) to send data to and from the memory cells. Each memory cell is configured with a GST based storage element 102, which with reference to FIG. 2 includes a top electrode 28, a GST material 26 capable of stable transition between amorphous and crystalline phases and a heater 22. The heater 22 constricts current flow to elevate the temperature of the GST material 26, necessary in forming the programmable volume 29. The GST based storage element 102 further connects to a self-aligned bottom electrode 106, and a vertical P-N diode connected in series with anode 108 and cathode 110.

The cathode 110 is further connected to a wordline 112 formed in an N+ doped base in the semiconductor layer 116, in this example doped with a P-type dopant. In other examples, other dopant materials are used consistent with the formation of the memory cell diode. Specifically, FIG. 9 shows a “P+/N” diode where the N-doped cathode 110 connects to the N+ doped wordline 112. N+ doping results in lower resistance, which minimizes signal loss when circuitry (described below) provides a positive bias across the memory cell diode. Specifically, the cathode 110 is forced to a lower potential (or voltage) than the anode 108, by lowering the wordline 112 potential relative to the bitline 104, and thereby causing diode conduction and a “connection” between the GST based storage element 102 and the wordline 112. In other embodiments, an “N+/P” diode is used where the N+ anode connects to the self-aligned bottom electrode 106 and the P cathode connects to a P+ doped wordline with a reversal of the wordline 112 and bitline 104 potentials required to access the memory cell data. A wordline strap 114 uses the second metal layer (M2) to reduce the word line resistance. A wordline strap can be used for every n phase change memory (PCM) cells, n being an integer, for example, n is 256. The choice of how often to connect (e.g. “strap”) the wordline 112 with the low resistance strap 114 is made by strapping often enough to lower the word line resistance between a driver and the worse case memory cell (the cell furthest from the strap connection), but not strapping so often as to significantly increase the overall memory array size.

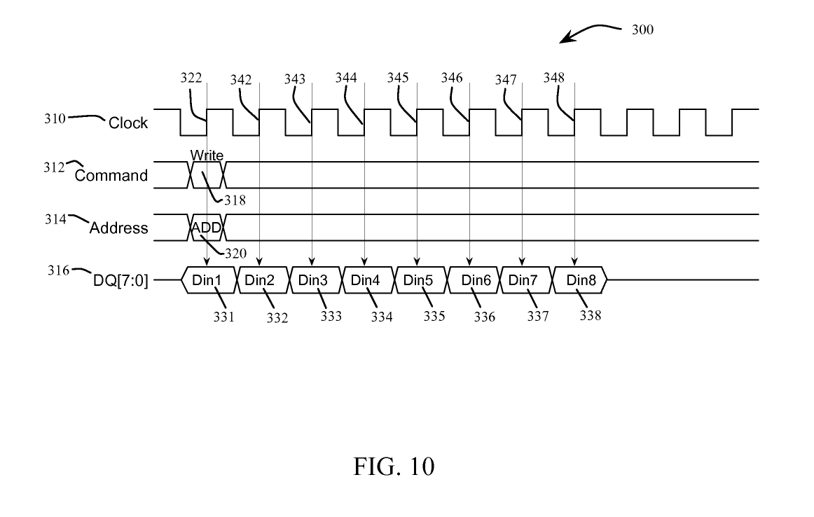

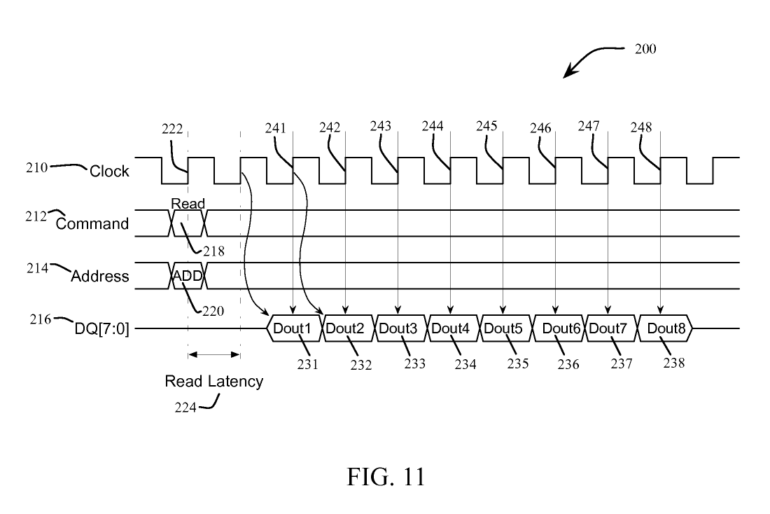

To improve WRITE and READ performance, a burst read with prefetch and a burst write with buffered data can be used as shown in FIGS. 10 and 11.

Referring to FIG. 10, a command 312 (e.g. WRITE 318) and an address 314 (e.g. ADD 320) are latched at clock edge 322. A series of data-words 316, specifically 331 through 338 is written on successive clock edges 322 through 348. The series of data words are prefetched with the first data word 331 available concurrent with the ADD 321 and WRITE command 318. Similar to the READ operation described for FIG. 11, the data-words 316 are written from sequential memory addresses starting with the base address ADD 320.

In PCM devices, the memory cell resistance for both SET and RESET states are tightly controlled to minimize bit error rate (BER), improve memory cell reliability, improve sensing speed, reduce sensing power and extend device lifetime. BER refers to the rate at which memory cells fail to provide the correct state after being programmed. A memory cell that is marginally programmed can still fail occasionally due to random noise, from power supply bounce for example. Memory cell reliability refers to the ability for a memory cell to perform as well “in the field” or the customer site as it does when tested by the manufacturer. Sensing speed is improved by increasing the signal available to the sense amplifier. Sensing power is reduced in one example, by shortening the duration that current sources must be on. Device lifetime refers to the time that a device will continue to properly function despite the effects of aging. An example of device aging is a shifting of a transistor threshold due to migration of dopants used to adjust the threshold.

Referring to FIG. 11, the burst operations as shown use a single data rate (SDR) timing where one edge of the clock 210 is used to latch data. Additional performance is obtained by using a double data rate (DDR) where both edges of the clock 210 are used to latch data. With reference to FIG. 11, the clock 210 is used to latch a command 212, (e.g. READ 218) and an address 214, (e.g. ADD 220) with a clock edge 222. The address ADD 220 defines the starting location for reading the series of data-words 216, with each data-word read to a sequential memory address. A latency 224 is added to allow time to buffer the data to be read, for example latching the data in a register. The data is then read to the memory with a series of data-words 216, specifically 231 through 238 (e.g. eight words), transferred to the memory at clock edges 241 through 248, with one clock edge used for each data-word. The “data-word” may comprise single byte or multiple byte data.

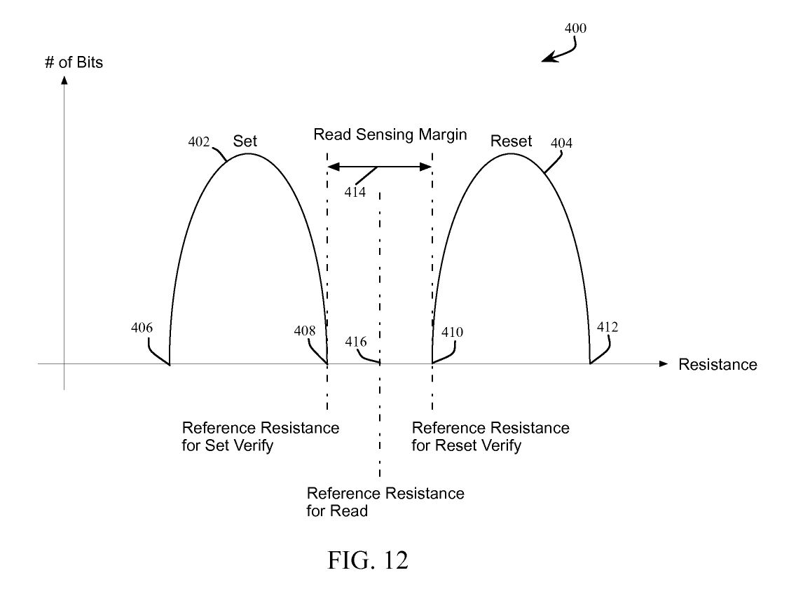

With reference to FIG. 12, a SET state 402 has a range of resistance values 406 to 408. The RESET state 404 has a range of resistance values 410 to 412. The separation of the two resistance ranges defines a read sensing margin 414. During a read operation, the sense amplifier uses a reference resistance for reading 416 that can be set anywhere within the read sensing margin 414. In one example, the reference resistance for read is centered between the highest SET state resistance 408 and the lowest RESET state resistance 410. During a write verify operation, a reference resistance for set verify 408 is used to verify that a SET state was properly programmed in the memory cell. Similarly, a reference resistance for reset verify 410 is used to verify that a RESET state was properly programmed in the memory cell.

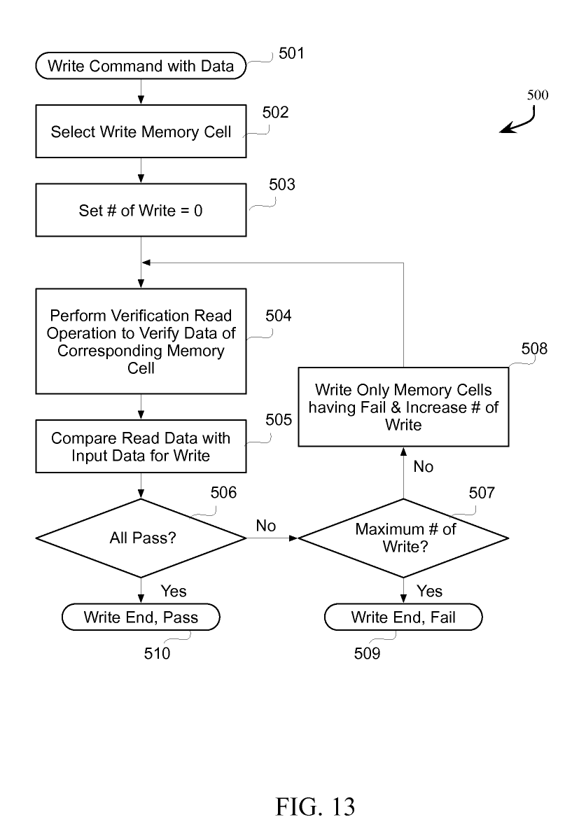

FIG. 13 depicts a flow chart of a WRITE operation. A write command with data is interpreted by the PCM device and performed at step 501, and as further described in FIG. 10. At step 502, the memory cell corresponding to the memory address is selected with row and column decoders and the data 231-238 is buffered in a register for the write drivers. At step 503 a write counter is initialized to a zero value to indicate that zero writes have been performed. At step 504, a write verify operation is performed for the selected memory cells comprising sensing the stored data with a sense amplifier. At step 505, the read data and the input data are compared. At step 506, if the comparison of step 505 passes, then the write operation ends at step 510, otherwise the total number of write operations is assessed at step 507. If the total number of write operations (e.g. a current value) is equal to the maximum permissible number of write operations (e.g. a maximum value) then proceed to step 509 to indicate a write failure. In one example, a write failure sets a fail flag. If the number of write operations is less than the maximum permissible number of write operations then proceed to step 508. At step 508, only the memory cells bits in the data-word that failed are rewritten, the write counter is incremented and proceed to step 504.

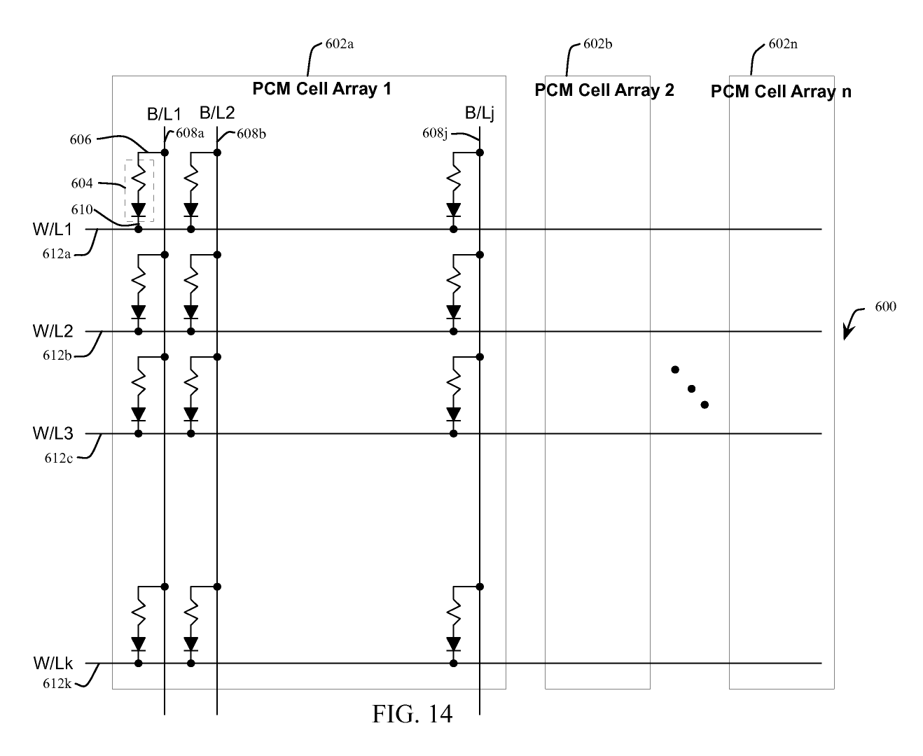

FIG. 14 shows a schematic view of a plurality of PCM cell arrays 602a through 602n (generally 602) according to an embodiment. The PCM cell arrays 602 include a plurality of memory cells 604 with a first terminal (e.g. top electrode) 606 connected to a corresponding bit-line (B/L) 608a of a plurality of bit-lines 608a through 608j (generally 608). The memory cells 604 have a second terminal 610 connected to a corresponding word-line (W/L) 612a of a plurality of word-lines 612a through 612k (generally 612). Each of the plurality of PCM cell arrays 602 is connected to a plurality of bitlines 608 and wordlines 612. The bitlines 608 are arranged orthogonal to the wordlines 612 with each memory cell 604 forming a cross-point connection when the bitlines 608 and wordlines 612 are appropriately biased to cause the switching element of the memory cell 604 to conduct. The bit-lines are also referred to as “columns” and the word-lines are referred to as “rows.” A data-word is stored and retrieved from the PCM cell arrays 602 by selecting a wordline 612 corresponding the location of all of the data-word and driving or sensing changes onto the bitlines 308 that correspond to the various bits of the data-word. A data-word can be stored in adjacent memory cells 604, which share a common wordline 612, in one example. In other examples, the data-word is stored in memory cells 604 that are not physically adjacent to provide “sparcity.” Sparcity reduces the peak current requirements of power supply busses that supply power to sensing and driving circuits. In another example, the data-word is comprised of memory cells 604 that are in one or more PCM cell arrays 602, either on the same PCM structure or on different PCM structures.

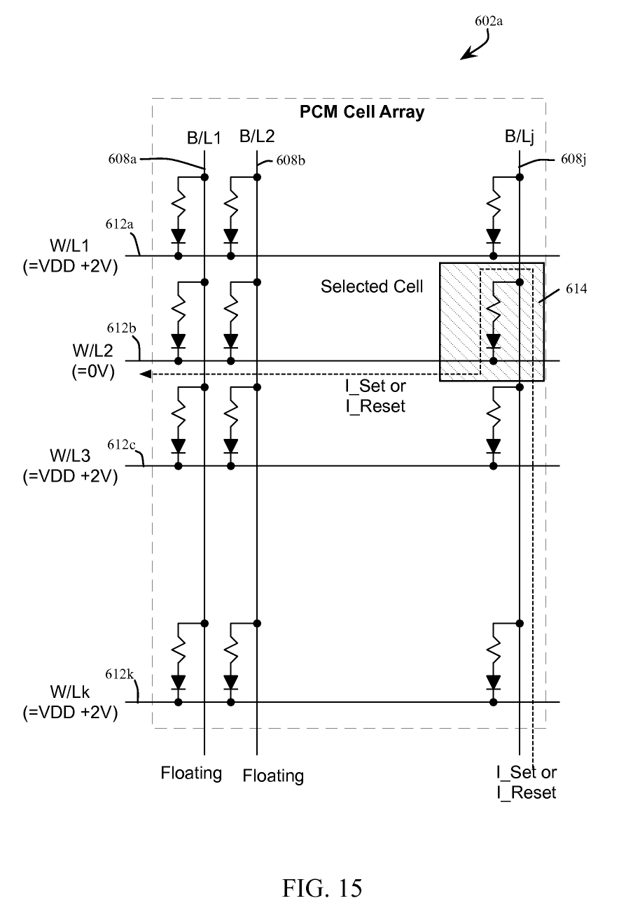

FIG. 15 shows the PCM cell array 602a in FIG. 14 with biasing for a WRITE operation. Referring to FIG. 15, the wordline 612b is selected by changing its bias to 0V, while the unselected wordlines 612a and 612c through 612k remain unselected with a bias of VDD+2V. In the particular example, VDD is 1.8V and the technology uses a 0.18 μm minimum feature size. However it should be understood that other voltages, process technologies and cell characteristics are comprehended within the scope of the invention. Write current with a value of either “I_Reset” or “I_Set” from a write driver (not shown) flows to the selected word-line 612b through a selected cell 614 and the selected bit-line 608j, while unselected bit-lines (e.g. 608a, 608b and others not shown) are left in a high impedance “floating” state, with the bit-line potential held up by the parasitic capacitance of the bit-line. Unselected cells connected to either an unselected word-line or a floating bit-line are reverse biased because the cathode of the diode switching element in each unselected memory cell is biased to a higher potential than the respective anode of the diode switching element, and thus no current flows through these unselected cells. More specifically, the diode switching elements in each unselected memory cell are reverse biased by 2V in the embodiment shown in FIG. 15. Although each diode will cease to conduct substantial current when the anode potential is at or below one diode threshold (typically 0.7V) of its cathode potential, the prevention of subthreshold current conduction requires a greater amount of reverse bias (e.g. 2V in this embodiment). The requirement to suppress subthreshold leakage of the unselected memory cells during a WRITE operation helps reduce spurious weak programming of unselected memory cells, thereby reducing the “signal margin” or the sensing voltage (or current) difference between the two programmed states. The issue of maintaining a wide sense margin is even more critical when the PCM memory cells are programmed to four different levels in a further adaptation to the embodiment shown in FIG. 15. Each of the PCM cell arrays 602 in FIG. 14 is biased for a WRITE operation in a similar manner to that described for PCM cell array 602a. A similar requirement to adequately reverse bias the unselected memory cells occurs with either the FET based or bipolar based switching element shown in FIGS. 6 and 7 respectively. In the case of a FET-based switching element, the gate to source potential must be well below the FET threshold including any body effects. In the case of the bipolar-based switching element the base-emitter diode must be adequately reverse biased to prevent conduction.

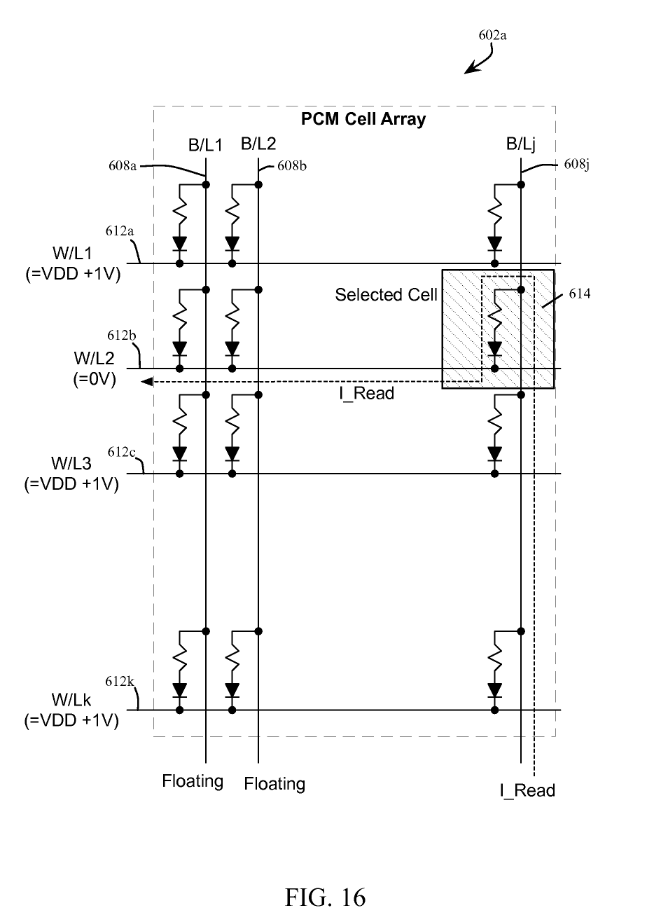

FIG. 16 shows the PCM cell array 602a of FIG. 14 biased for a READ operation. Referring to FIG. 16, word-line 612b is selected by changing its bias to 0V, while the unselected word-lines 612a and 612c through 612k remain unselected with a bias of VDD+1V. For example, VDD is 1.8V and the technology uses a 0.18 um minimum feature size. It should be understood that other voltages, process technologies and cell characteristics are comprehended in other embodiments. Read current “I_Read” from a sense amplifier (or “sense amp” (not shown)) flows to the selected word-line 612b through the selected cell 614 and the selected bit-line 608k, while unselected bit-lines (e.g. 608a, 608b and others not shown) are left in a high impedance “floating” state, with the bit-line potential held up by the parasitic capacitance of the bit-line. Unselected cells connected to either an unselected word-line or a floating bit-line are reverse biased and thus no current flows through these unselected cells. Each of the PCM cell arrays 602 in FIG. 14 is biased for a READ operation in a similar manner to that described for PCM cell array 602a. Similar to the WRITE case, unselected memory cells have their respective diode switching elements reverse biased beyond the level where substantial current flows and to a level required to suppress subthreshold leakage through each diode. The requirement to suppress subthreshold leakage of each of the unselected memory cells is further compounded by the cumulative effect of unselected memory cells on a bitline that has a selected cell (e.g. cell 614 on bitline 608j). For example, if bitline 608j has 256 memory cells, one of which is selected, the cumulative leakage of 255 poorly deselected memory cells will deflect the bitline 608j potential, thereby reducing the available sense signal. A similar requirement to adequately reverse bias the unselected memory cells occurs with either the FET based or bipolar based switching element shown in FIGS. 6 and 7 respectively. In the case of a FET-based switching element, the gate to source potential must be well below the FET threshold including any body effects. In the case of the bipolar-based switching element the base-emitter diode must be adequately reverse biased to prevent conduction.

An example of voltage bias conditions and current conditions for diode-based PCM devices as shown in FIGS. 14, 15 and 16 are summarized in Table 2 (Kwang-Jin Lee et al., “A 90 nm 1.8 V 512 Mb Diode-Switch PRAM With 266 MB/s Read Throughput,” IEEE J Solid-State Circuits, vol. 43, no. 1, pp. 150-162, January 2008). All voltage and current values are examples for the shown embodiments. Other values consistent with a process technology and cell characteristic are within the scope of the invention.

TABLE 2
Voltage and Current Conditions for a diode-based PCM

| | Reset Write | Set Write | Read |
|---|---|---|---|
| Unselected W/L | VDD + 2 V | VDD + 2 V | VDD + 1 V |
| Selected W/L | 0 V | 0 V | 0 V |
| Unselected B/L | Floating | Floating | Floating |
| Selected B/L | l_Reset | l_Set | l_Read |

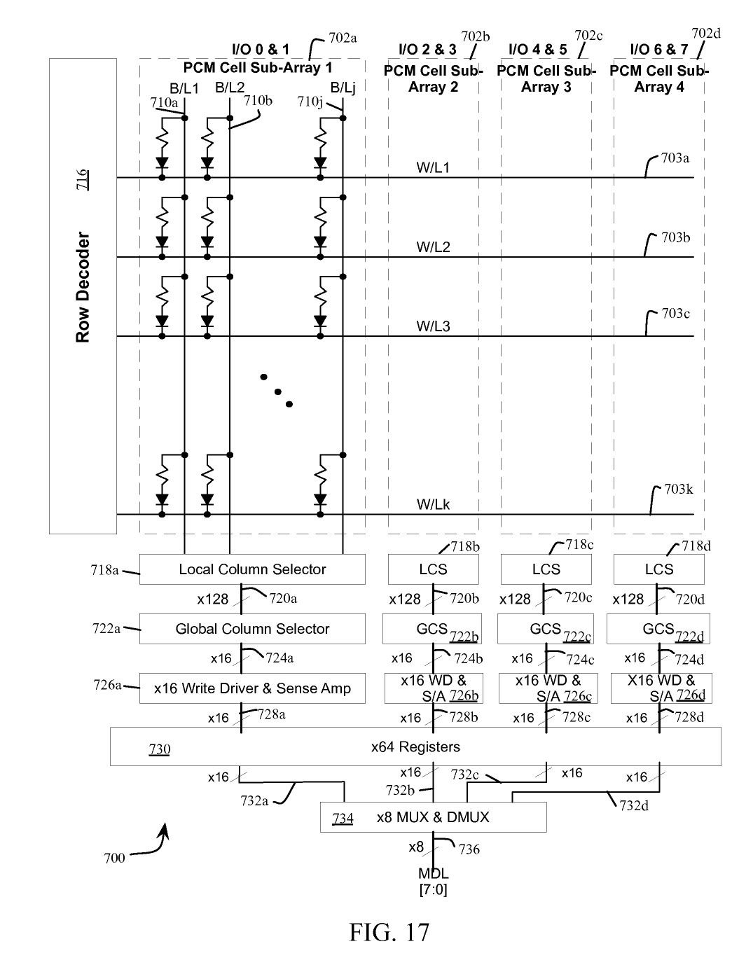

FIG. 17 depicts a bank architecture 700 of a PCM device in accordance with one embodiment of the present invention. The bank architecture 700 comprises four sub-arrays 702a through 702d and an eight bit data path MDL [7:0] 736. The first sub-array 702a provides MDL[0:1], the second sub-array 702b provides MDL[2:3], the third sub-array 702c provides MDL[4:5] and the fourth sub-array provides MDL[6:7].

A row decoder 716 selects one of the rows (e.g wordlines) 703a through 703k (generally 703). A local column selector 718a through 718d (generally 718) selects 128 bits (e.g. 720a) from 128 bitlines in a sub-array 702. A global column selector 722a through 722d (generally 722) selects 16 bits (e.g. 724a) from the 128 bits selected by the local column selector 718. A write driver and sense amplifier block 726a through 726d (generally 726) writes 16 bits (e.g. 724a) of data to the global column selector 722 and senses 16 bits of data from the global column selector 722 (e.g. 728a). A 64 bit register 730 receives 16 bits of data from each of the four write driver and sense amplifier blocks 726, and receives four groups of 16 bits 732a through 732d (generally 732) from an 8:1 multiplexor (MUX) and demultiplexor (DMUX) 734, which sends and receives 8 bits as MDL[7:0] 736.

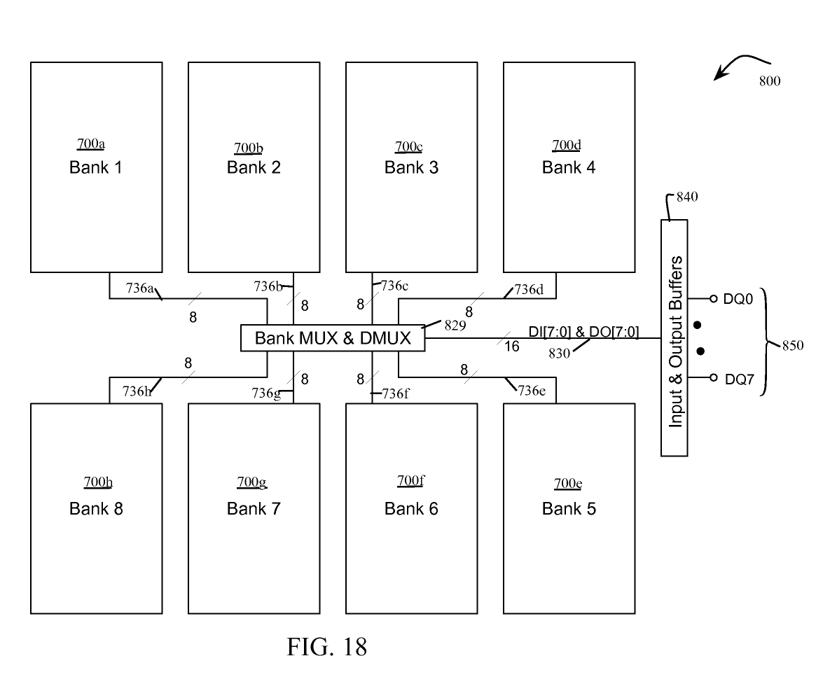

FIG. 18 a high level PCM device architecture with eight banks 700a though 700h (generally 700), each bank 700 configured as shown in FIG. 17. Each of the eight banks comprises an MDL[7:0] port. For example, Bank 1 700a has an MDL[7:0] port 736a. Each of the eight ports 736a through 736h (generally 736) connects to a bank MUX and DMUX 829, which selects one of the eight ports 736 to communicate with an I/O buffer 840. The I/O buffer 840 drives and receives an eight bit bus 850.

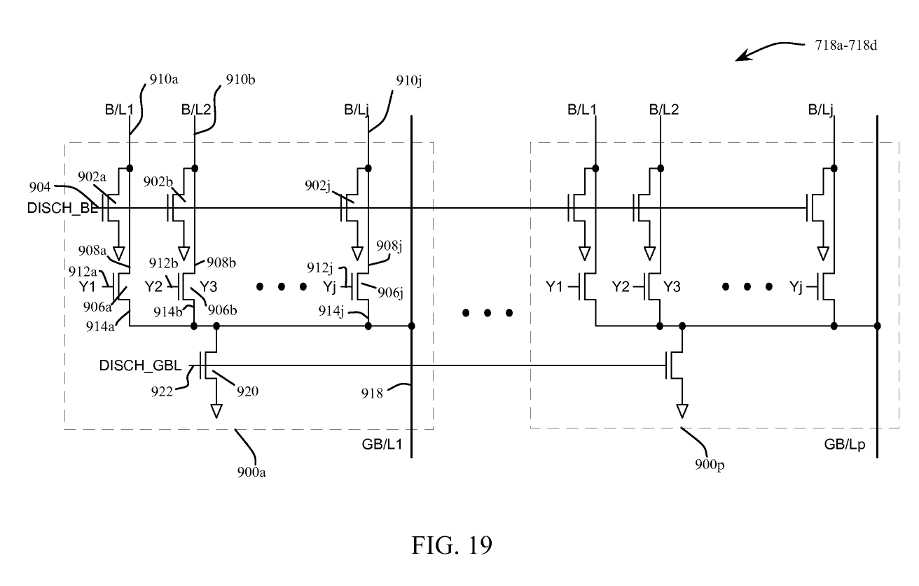

FIG. 19 shows an example of one of the local column selectors 718a-718d shown in FIG. 17. Referring to FIG. 19, the local column selector has “p” groups of local column decoders 900a through 900p, p being an integer greater than one. Each of the column decoders includes “j” NMOS bit-line discharge transistors 902a through 902j, each controlled by a bit-line discharge signal “DISCH_BL” 904. Each of the column decoders includes “j” NMOS column select transistors 906a through 906j. The sources 908a through 908j of the column select transistors 906a through 906j are connected to respective ones of bit-line 910a through 910j. The gates 912a through 912j of the column select transistors 906a through 906j are connected to respective ones of local column select lines 912a to 912j. The drains 914a through 914j of the column select transistors 906a through 906j are connected to a common global bit-line 918. The global bit-line 918 is connected to the drain of an NMOS transistor 920, the source of which is connected to the ground. The gate 922 of the NMOS transistor 920 is connected to a common global bitline discharge signal source (not shown) to provide a common global bitline discharge signal “DISCH_GBL” 922. The common global bit-line discharge signal “DISCH_GBL” 922 fed to the gate of an NMOS transistor 920 controls the discharge of the global bitline 918.

With reference to FIGS. 15 and 19, bitlines 608a, 608b and 608j correspond to the bitlines 910a, 910b and 910j. During the WRITE operation phase, when the cell 614 is being written, the bitline discharge signal “DISCH_BL” 904 and the common global bitline discharge signal “DISCH_GBL” 922 are low to deactivate the respective discharge paths. Gates 912a and 912b are low to deactivate the column select transistors 906a and 906b thereby floating bitlines 910a and 910b. Gate 912j is held high to activate the column select transistor 906j and connect the global bitline 918 to the local bitline 910j associated with the memory cell 614 (of FIG. 15) being written.

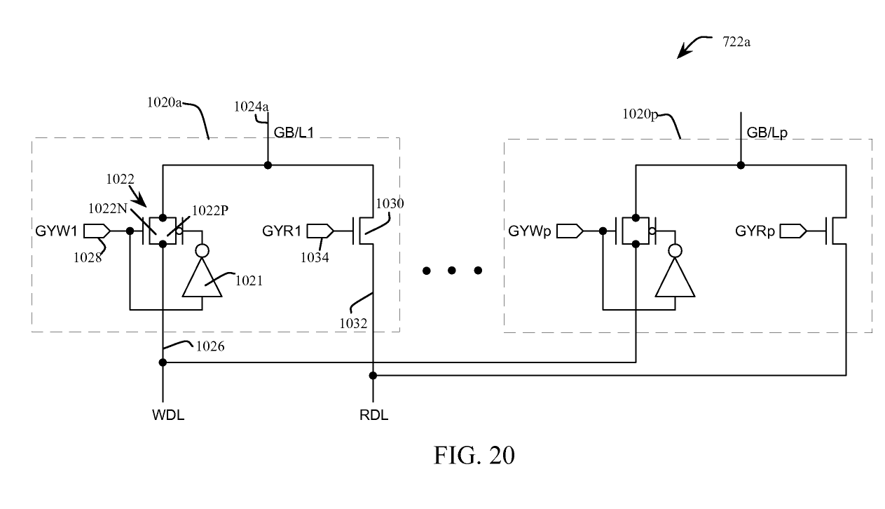

FIG. 20 shows an embodiment of the global column selector 722a shown in FIG. 17. Each global column selector has “p” groups of global column decoders 1020a through 1020p, each of which includes a full CMOS transmission gate 1022 and an NMOS transistor 1030. The global column decoders 1020a through 1020p share a common write data-line (WDL) 1026. For example, the first global column decoder 1020a includes a full CMOS transmission gate 1022 between a global bit-line “GB/L1” 1024a and the WDL 1026. The transmission gate 1022 is formed by an NMOS transistor 1022N in parallel with a PMOS transistor 1022P, both located between the global bit line 1024a and WDL 1026. The gate of NMOS transistor 1022N is connected to an input 1028 to which a write global column select signal “GYW1” is fed. The input 1028 is connected via an inverter 1021 to the gate of the PMOS transistor 1022P. The transmission gate 1022 is controlled by the write global column select signal GYW1. The global column decoders 1020a through 1020p also share a common read data-line (RDL) 1032. The first global column decoder 1020a includes an NMOS transistor 1030 between the global bitline 1024a and the common read data-line (RDL) 1032. The gate of the NMOS transistor 1030 is controlled by the read global column select signal GYR1. The global column selector 1020a is used to select one of the groups of bits from local column selectors 718a shown in FIG. 17 and to provide selection of either write data controlled by GYW1 1028 or read data controlled by GYR1 1034. In one preferred embodiment, only one of the GYW1 1028 and GYR1 1034 control signals are selected at one time. In another embodiment, both GYW1 1028 and GYR1 1034 control signals are selected at the same time to use the global column selector 722a as a data bypass useful for testing purposes to control and observe data flow independent of the functionality of the memory arrays. The embodiment in FIG. 20 is advantageous for architectures that share a common READ and WRITE data bus (“RDL” and “WDL”).

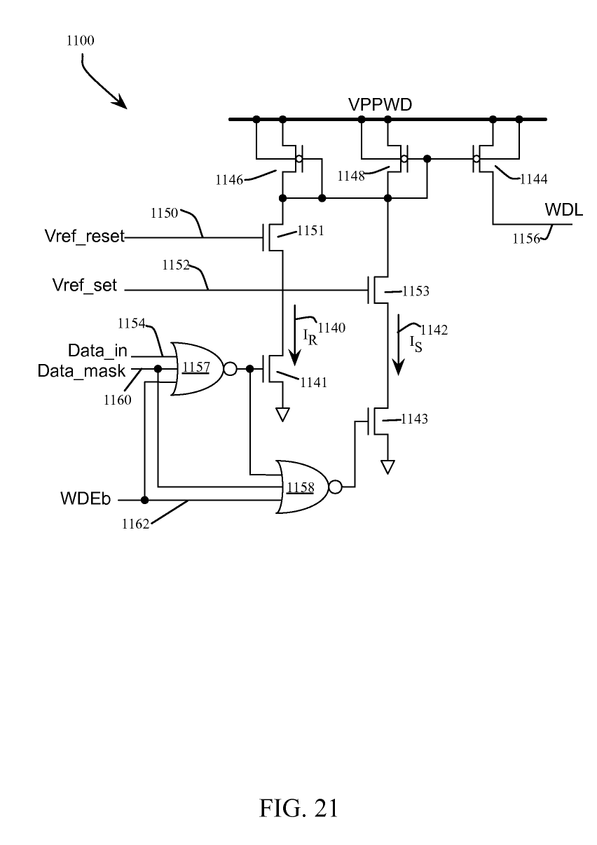

The embodiment 1100 in FIG. 21 is an example of the write driver portion of the write driver and sense amplifier block 726a shown in FIG. 17. Referring to FIGS. 17 and 21, in response to a data input signal 1154 and control voltages 1150 and 1152, two currents “I_{R}” 1140 and “I_{S}” 1142 flow. The current 1140 flows through the transistors 1146, 1151 and 1141 and is gated by transistors 1151 and 1141 by several conditions. Firstly, the Vref_reset control voltage 1150 must be high to enable RESET programming. Secondly, the Data_in signal 1154 must be low (or at a logical “0” state as shown in Table 1). Finally, both the Data_mask 1160 and the inverted write data enable (WDEb) 1162 must be low. The WDEb signal 1162 generally enables the write driver. The Data_mask signal 1160 enables the write driver when the contents read from a memory (e.g. write verify) do not match the input data. In other words, a previous write operation needs to be repeated. When all of these conditions are met, transistors 1151 and 1141 are both on and current 1140 is allowed to flow.

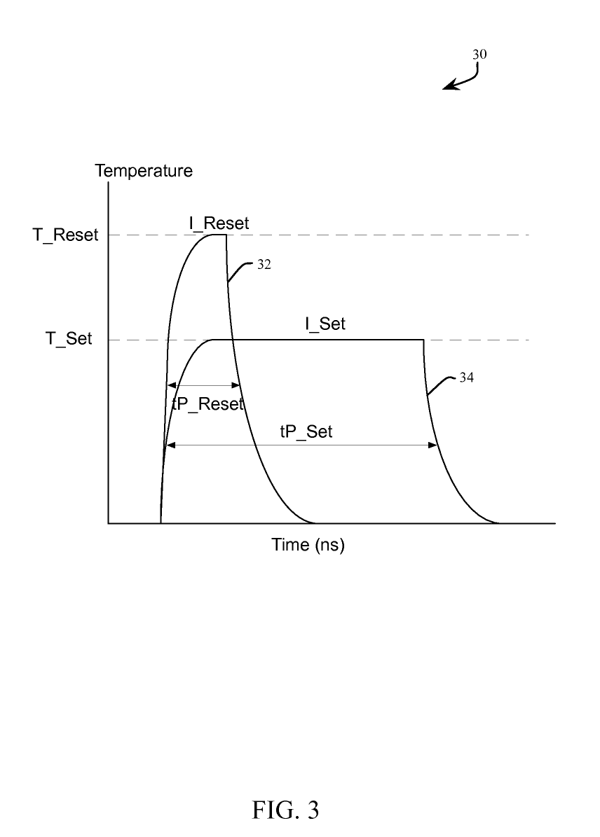

The current 1142 flows through the transistors 1148, 1153 and 1143 and is gated by transistors 1153 and 1143 by two conditions. Firstly, the Vref_set control voltage 1152 must be high to enable SET programming. Secondly, the Data_in signal 1154 must be high (or at a logical “1” state as shown in Table 1). Finally, both the Data_mask 1160 and the inverted write data enable (WDEb) 1162 must be low. When all of these conditions are met, transistors 1153 and 1143 are both on and current 1142 is allowed to flow. Separate control of the Vref_reset 1150 and Vref_set 1152 control voltages is used because the RESET and SET programming intervals (described as the Write Pulse in Table 1) are required to properly alter the programming volume 49 shown in FIG. 4B. The Data_in signal 1154 controls the transistors 1141 and 1143 through a pair of NOR gates 1157 and 1158 respectively. Specifically, Data_in 1154 is inverted by NOR gate 1157 to turn on transistor 1141 when Data_in 1154, Data_mask 1160 and WDEb 1162 are low. NOR gate 1157 also buffers the transistor 1141 so a plurality of write driver circuits 1100 each with a transistor 1141 connected in parallel do not impose an excessive capacitive load on the control signal Data_in 1154, which would reduce the transition time of the Data_in 1154 signal. The Data_in 1154 signal is inverted by the output of NOR gate 1157 feeding into a second NOR gate 1158, the output of which controls the gate of transistor 1143 and turns on transistor 1143 in response to a high voltage on the Data_in 1154 signal. With reference to Table 1 and FIGS. 4A and 4B, a high voltage on Data_in 1154 corresponds to a logical “1” state or the SET state. A low voltage on Data_in 1154 corresponds to a logical “0” state or the RESET state. A current mirror formed by PMOS transistors 1146 and 1144 mirrors the current 1140 to WDL 1156 during a RESET operation. A current mirror formed by the PMOS transistors 1148 and 1144 mirrors the current 1142 to WDL 1156 during a SET operation. The write driver 1100 provides a higher current for RESET shown as I_Reset and a lower current for the SET operation shown as I_Set in FIG. 3. The magnitude of the RESET current 1140 is proportional to the ratios of the length of transistors 1144 and 1146. Similarly, the magnitude of the SET current 1142 is proportional to the ratios of the length of transistors 1144 and 1146.

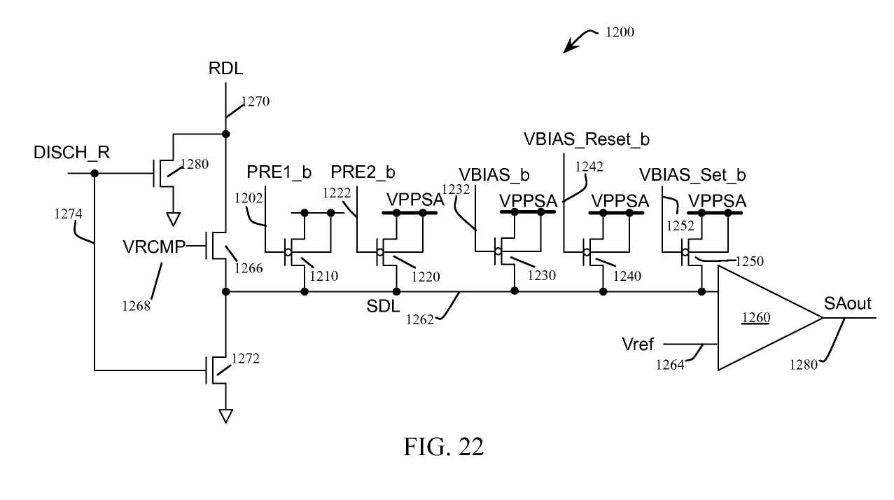

FIG. 22 is an example of a sense amplifier portion 1200 of the write driver and sense amplifier block 726a shown in FIG. 17. The sense amplifier 1200 reads data from a bitline in a memory (e.g. the PCM cell array 702a in FIG. 17). The bitline within the memory array is selected by the local column selector 718a, the global column selector 722a further selects 16 bits from the local column selector 718a and the data passes from the PCM cell array 702a to the sense amplifier 1200 on a read data line “RDL” 1270 shown in FIG. 22.

With reference to FIG. 22, a PMOS bit-line precharge transistor 1210 is controlled by “PRE1_{—}b” 1202 with a voltage source equal to VDD. Another PMOS bit-line precharge transistor 1220 is controlled by “PRE2_{—}b” 1222 with a voltage source equal to VPPSA, where VPPSA is typically greater than VDD. A PMOS bit-line bias transistor 1230 is controlled by “VBIAS_b” 1232 with a voltage equal to VPPSA. Transistor 1230 provides the reference resistance fore read 416 shown in FIG. 12. A PMOS bit-line bias transistor 1240 is controlled by VBIAS_Reset_b 1242 with a voltage source equal to VPPSA. Transistor 1240 provides the reference resistance for reset verify 410 shown in FIG. 12. A PMOS bit-line bias transistor 1250 is controlled by VBIAS_Set_b 1252 with a voltage source equal to VPPSA. Transistor 1250 provides the reference resistance for set verify 408 shown in FIG. 12.

The drains of the PMOS transistors 1210, 1220, 1230, 1240 and 1250 are commonly connected to a sensing data-line “SDL” 1262. A differential voltage amplifier 1260 has two inputs one of which is connected to SDL 1262 and the other of which is connected to a reference voltage “Vref” 1264. An NMOS voltage clamp transistor 1266 is between RDL 1270 and the SDL 1262 and is controlled by “VRCMP” 1268. An NMOS transistor 1272 is controlled by “DISCH_R” 1274 for SDL 1262 discharge. An NMOS transistor 1280 is controlled by “DISCH_R” 1274 to discharge RDL 1270. The discharge transistors 1272 and 1280 discharge the SDL 1262 and RDL 1270, respectively, in preparation for a READ operation. In one example, the NMOS transistor 1280 is larger than the NMOS transistor 1272 to discharge RDL 1270 at the same rate as SDL 1262, RDL 1270 having a higher capacitive loading than SDL 1262.

The two precharge transistors 1210 and 1220 provide for a more gradual precharge rate on the bitlines. Advantageously, the two slope precharging approach reduces the burden on a charge pump used to supply the VPPSA voltage. VPPSA is boosted from VDD with a charge pump. In one embodiment, VPPSA is VDD+2V. Charge pumps have limited current sourcing ability for a given area. The two stage precharge scheme first uses PRE1_{—}b 1202 to bring SDL 1262 from 0V to VDD by sourcing current directly from VDD. The second stage then uses PRE2_{—}b 1222, which charges SDL 1262 from VDD to VPPSA using current supplied by the VPPSA charge pump. By precharging SDL to VPPSA, adequate read voltage margin for diode based PCM cells is ensured.

The bias transistor 1230 provides a load current equal to the current sunk by the selected memory cell 614 (of FIG. 16), excluding parasitic currents and converts the current drawn from the selected memory cell into a voltage on SDL 1262. The amplifier 1260 then compares the developed voltage on SDL 1262 against the reference voltage “Vref” 1264, and drives a sense amplifier output “SAout” 1280 high if SDL 1262 exceeds the reference voltage Vref 1264. Referring to FIGS. 4, 16 and 22, if the memory cell 614 is programmed to the RESET state, amorphous material 49 will be present, which will result in higher resistance between the top electrode 48 and the bottom electrode 44, compared to the SET state. Higher resistance will result in a larger voltage drop across the memory cell 614 and consequently a higher voltage at SDL 1262 is sensed than when a SET state is sensed.

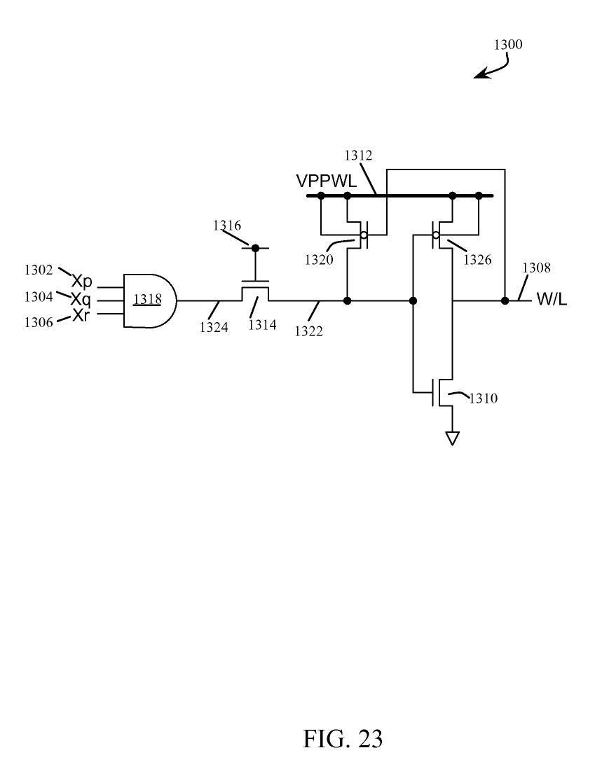

FIG. 23 shows an embodiment 1300 of a single row decoder being one of a plurality of row decoders shown as 716 in FIG. 13. The row decoder 1300 is enabled by pre-row-decoder outputs Xp 1302, Xq 1304 and Xr 1306, which control an AND gate 1318. The output of the row decoder 1300 is connected to a corresponding wordline “W/L” 703, which connects to a wordline of a diode-based switching element 614 as shown in FIGS. 15 and 16. W/L 1308 is driven to 0V when selected and to VPPWL 1312 when unselected. In another embodiment, the row decoder 1300 is adapted for a FET-based or bipolar-based switching element by replacing the AND gate 1318 with a NAND gate.

Referring to the row decoder shown in FIG. 23, when each of Xp 1302, Xq 1304 and Xr 1306 are in the high state, the output of AND gate 1318 outputs the high state, turning on transistor 1310, which pulls W/L 1308 low. Accordingly, when Xp 1302, Xq 1304 and Xr 1306 are in the high state, then W/L 1308 is selected. If any one of Xp 1302, Xq 1304 or Xr 1306 are low, then AND gate 1318 outputs the low state and transistor 1326 pulls W/L 1308 high or to the unselected state. The value of VPPWL 1312 is VDD+2V during a WRITE operation and VDD+1V during a READ operation as previously discussed in FIGS. 15 and 16 and Table 2. The row decoder 1300 has a clamping transistor 1314 controlled by voltage 1316 to prevent VPPWL 1312 from sourcing excessive voltage back to the NAND gate 1318. The clamping transistor operates by “pinching off” the current flow from 1322 to 1324 when the voltage on 1322 (e.g. VPPWL) equals the voltage 1316 minus the threshold voltage of transistor 1314. The row decoder 1300 also uses a pull-up FET 1320 activated when W/L 1308 is low, or selected, thereby ensuring that selected wordlines (e.g. 612a, and 612c through 612k in FIGS. 15 and 16) will remain selected in the presence of noise coupling. In another embodiment of a row decoder for a diode-based memory, the AND gate 1318 is replaced with a NAND gate and an inversion stage is added between W/L 1308 and the wordline 612b, to enable the pull-up transistor 1320 when the row decoder is unselected. This ensures that unselected wordlines are not activated by noise coupling from other sources, for example noise from selecting 612b.

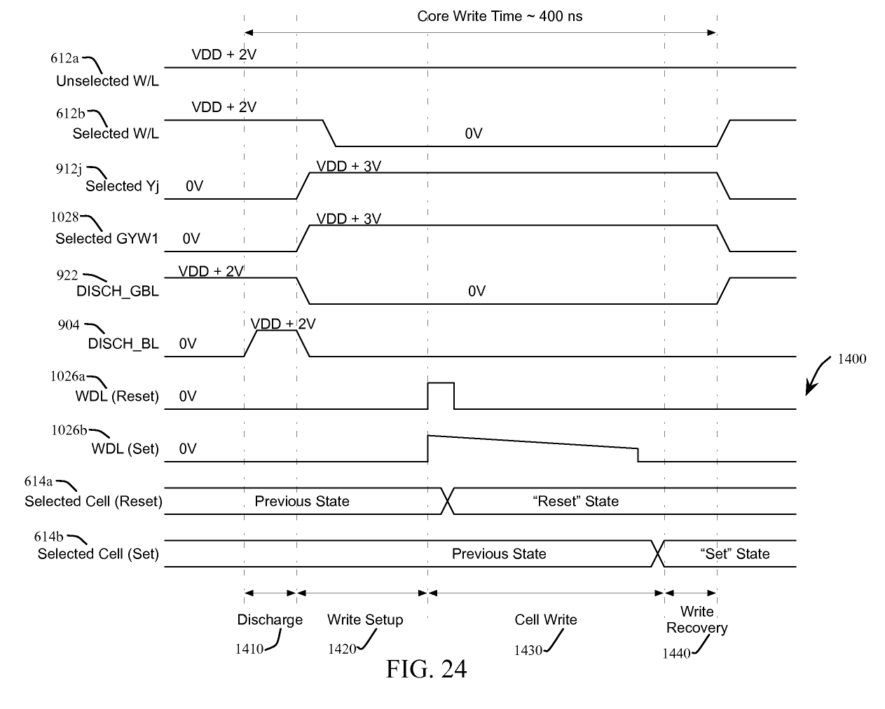

FIG. 24 shows a WRITE-operation timing diagram including four phases, namely “Discharge” 1410, “Write Setup” 1420, “Cell Write” 1430 and “Write Recovery” 1440. During the Discharge phase 1410, local bitlines and global bitlines are discharged to 0V. This is accomplished by raising the DISCH_BL 904 and DISCH_GBL 922 signals to VDD+2V. Raising DISCH_BL 904 and DISCH_GBL 922 to a voltage greater than VDD provides more drive current to discharge the bitline and global bitline, respectively. In another embodiment, DISCH_BL 904 and DISCH_GBL 922 are only raised to VDD and the Discharge phase 1410 is extended for longer discharge time.

Referring to FIGS. 15, 19, 23 and 24, during the Discharge phase 1410, the wordlines (e.g., wordlines 612a and 612c through 612k) are deselected by applying VDD+2V. Although the wordlines need only be raised to approximately one diode threshold above the bitline (e.g., the bitline 608j) potential to prevent the diode-based memory cells from conducting, raising the wordlines to VDD+2V ensures that the memory cells 614 shown in FIG. 15 will not conduct current while the bitlines are discharging. The bitlines (910a through 910j in FIG. 19) and the global bitlines (918 in FIG. 19) are also discharged by applying VDD+2V to DISHC_BL 904 and DISCH_GBL 922 respectively.

Referring to FIGS. 15, 19, 20, 21 and 24, during the Write Setup phase 1420, the local bitlines and global bitlines are allowed to “float” by deactivating DISCH_BL 904 and DISCH_GBL 922, respectively. A floating bitline means the bitline potential is not driven by a low impedance source (e.g. a driver) but can significantly maintain the previously potential with the parasitic capacitance of the bitline. The write driver output WDL 1156 shown in FIG. 21 is connected to a selected wordline (e.g. 612b in FIG. 15) through an inverter (not shown) to select the diode-based memory cell 614 to be written to. The bitline 608j (shown as 910j in FIG. 19) is selected by selecting Yj 912j in a local column selector and GYW1 1028 in a global column selector. The voltages applied to Yj 912j and GYW1 1028 are VDD+3V to ensure the full voltage range (e.g. VPPWD) of the WDL signal 1156 (shown in FIG. 21′) can pass from the write driver 1100 to the memory cell 614.

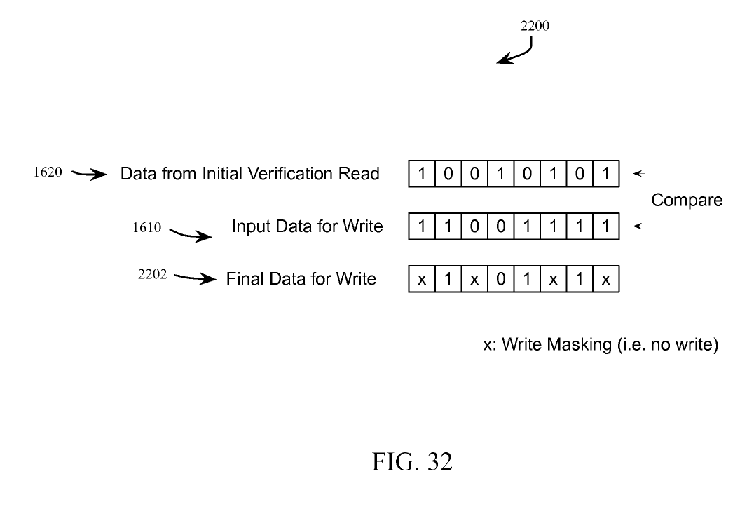

Referring to FIGS. 3, 4A, 4B, 15, 20, 21 and 24, during the Cell Write phase 1130, the cell 614 is written to the RESET state by fast quenching or to the SET state by slow quenching, respectively. The write driver 1100 provides the proper write current in accordance with the Data_in signal 1154, Data-mask signal 1160, WDEb 1162 and control signals 1150 and 1152 shown in FIG. 21. To write a RESET state to the memory cell 614 a short pulse is provided, shown as 1026a in FIGS. 24 and 32 in FIG. 3. To write a SET state to the memory cell 614 a longer pulse is provided, shown as 1026b in FIGS. 24 and 34 in FIG. 3.

During the Write Recovery phase 1440, the Chalcogenide compound 46 in FIG. 4A is given additional time to crystallize and cool. Following the Write Recovery phase 1440, the selected wordline 612b and the global bit-line discharge signal “DISCH_GBL return to VDD+2V. The local column select Yj 912j and global column select GYW1 1028 are turned off.

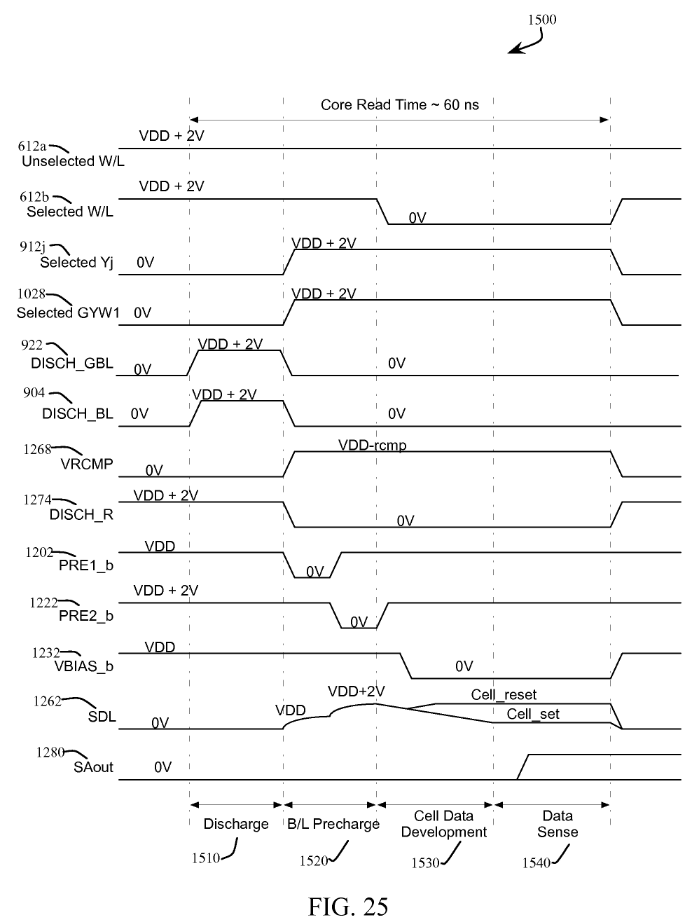

FIG. 25 shows a READ-operation timing diagram including four phases, namely “Discharge” 1510, “B/L Precharge” 1520, “Cell Data Development” 1530 and “Data Sense” 1540. During the Discharge phase 1510, the local bit-lines and global bit-lines are discharged by the DISCH_BL 904 and DISCH_GBL 922 signals, similar to the WRITE-operation shown in FIG. 24. In addition, RDL 1270 and the SDL 1262 signals are discharged by applying VDD+2V to the DISCH_R 1274 signal shown in FIG. 22.

Referring to FIGS. 19, 20, 22 and 25, during the bitline-precharge phase 1520, the local and global column select transistors, are turned on by the selected column select line Yj 912j and the global column select line GYW1 1028, respectively. VRCMP 1268 (shown in FIG. 22) is set to a “VDD-rcmp” voltage level, which will cause the clamping transistor 1266 to limit the voltage that can be passed from RDL 1270 to SDL 1262 to prevent the amplifier 1260 from saturating and limiting recovery time. In one embodiment, VDD-rcmp is set to VDD+3V thereby allowing a voltage of VDD+3V less the threshold of the clamping transistor 1266 to be passed from RDL 1270 to SDL 1262. The SDL 1262 is precharged to VDD+2V with a two-step precharge operation, first to VDD (1.8V for example) and then to VDD+2V by precharge signals PRE1_{—}b 1202 and PRE2_{—}b 1222 respectively.

Referring to FIGS. 16, 22 and 25, during the Cell Development phase 1530, the selected wordline 612b is biased to 0V. The bias transistor 1230 for SDL 1262 is enabled (shown in FIG. 22). During this period the selected memory cell 614 will draw current and cause SDL 1262 to change potential in accordance with the programmed state in the memory cell 614.

Referring to FIGS. 22 and 25, during the Data Sense phase 1540, the sense amplifier senses SDL 1262 and causes SAout 1280 to go high if SDL 1262 exceeds the reference voltage 1264. In one embodiment, the amplifier 1260 latches the state of SAout 1280 controlled by an additional control pin. In another embodiment, the amplifier 1260 includes hysteresis so that SAout 1280 will not toggle when SDL 1262 is equal to Vref 1264 during the cell data development phase 1530.

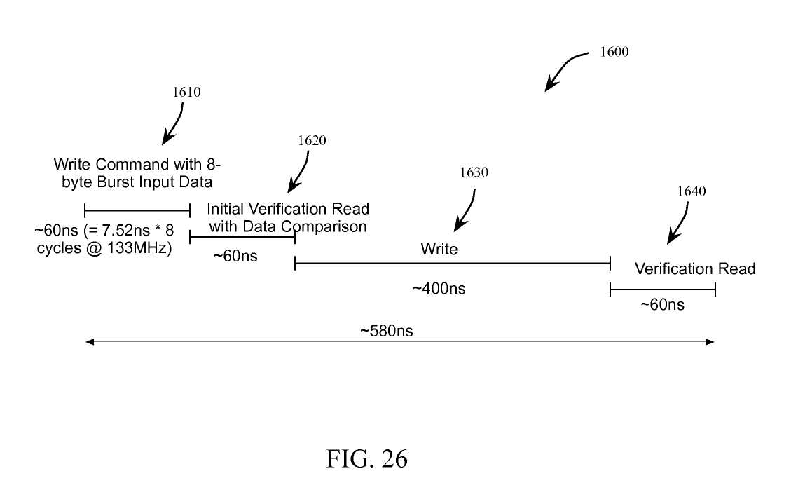

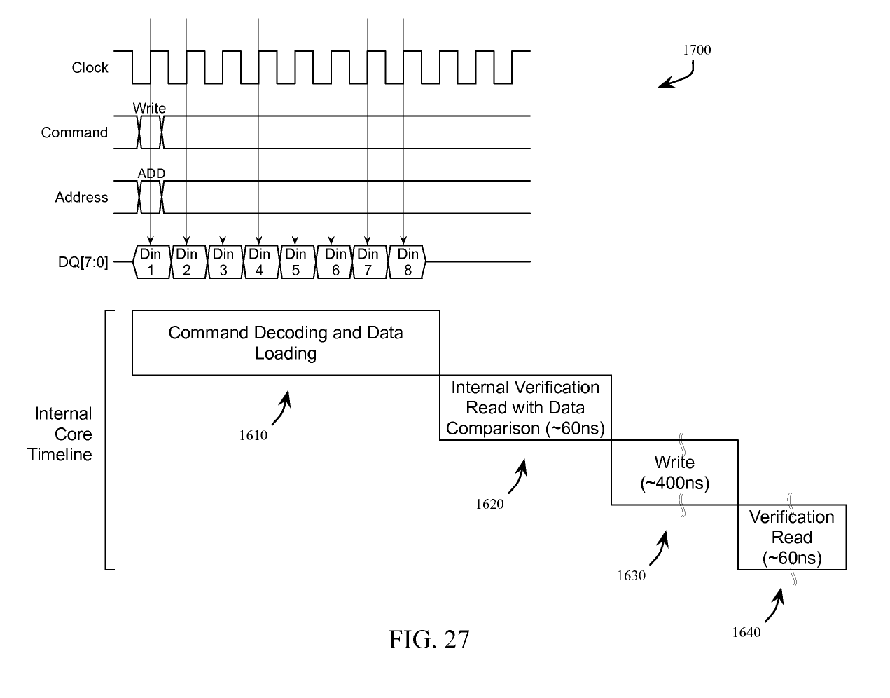

FIGS. 26 and 27 show the timing relationship for the various steps of verifying a successful WRITE operation to obtain the resistance distribution shown in FIG. 12. Referring to FIG. 26 and with reference to FIGS. 13 and 17, a WRITE command results in eight bytes of input data being loaded in register 730 at step 1610 (e.g. steps 501-503 in FIG. 13). In one embodiment, step 1610 takes approximately 60 ns to perform with a device having a 133 Mhz clock. At step 1620, the initial verification read with data comparison is performed in approximately 60 ns, substantially the same as the duration of step 1610. The verification read stores the result of the read in the write driver and sense amplifier block 726 (e.g. step 504 in FIG. 13). The data comparison (e.g. steps 505-506 in FIG. 13) occurs in the write driver and sense amplifier block 726 with exclusive-NOR gates for example. In another example, the data comparison occurs in the register. If the initial verification read and data comparison indicates a failed previous write operation (e.g. step 506) and the maximum number of writes have not been reached (e.g. step 507), then the memory is written at step 1630. In one embodiment, step 1630 takes approximately 400 ns. Step 1640 performs a subsequent verification read for write verification in approximately 60 ns. The total duration of steps 1610-1640 ns is approximately 580 ns.

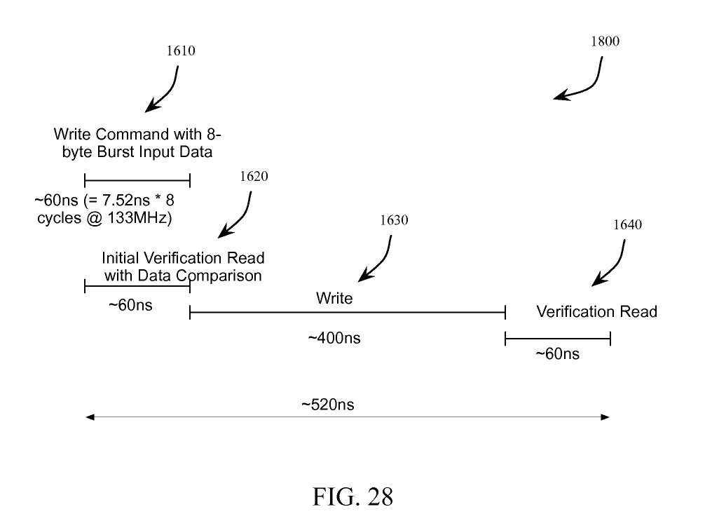

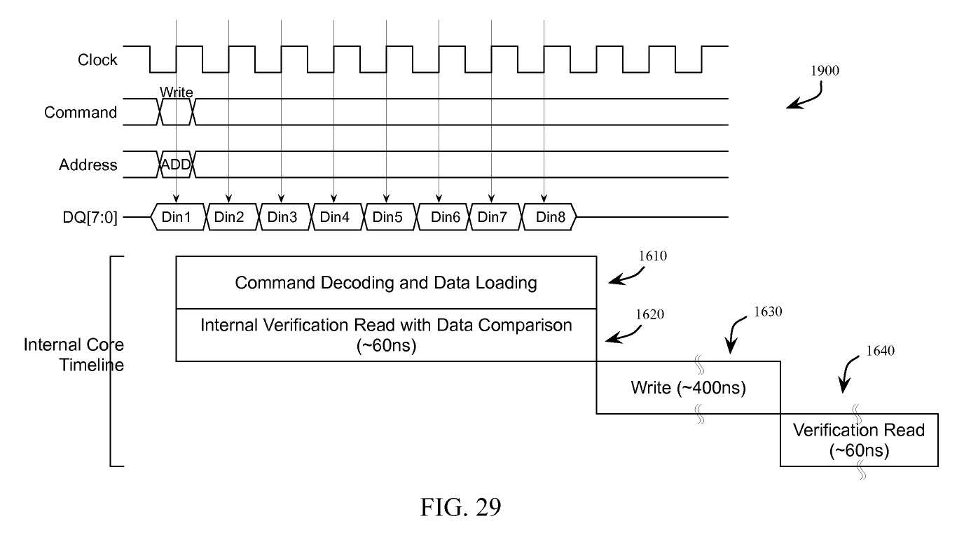

FIGS. 28 and 29 show the timing relationship according to embodiments of the present invention for the various steps of verifying a successful WRITE operation to obtain the resistance distribution shown in FIG. 12. In the embodiments of the present invention, the initial verification read (e.g. step 1610) is performed substantially contemporaneous with step 1620, with a total duration of steps 1610-1640 approximately equal to 520 ns.

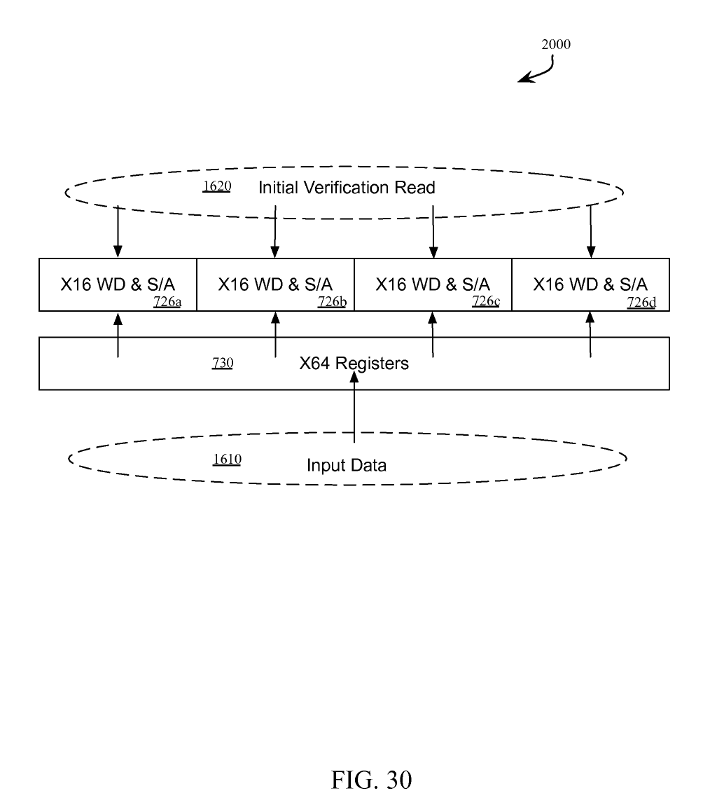

FIG. 30 shows the flow of data for performing the equivalence function in the write driver and sense amplifier block 726. The input data 1610 is held in the registers 730 and the verification read data is held in block 726. In one embodiment, the sense amplifier output 1280 (FIG. 22) and the input data 1610 store in the registers 730 are in communication, either directly or indirectly, with an exclusive-NOR gate. The output of the exclusive-NOR gate communicates with the write driver (FIG. 21), either directly or indirectly, as the Data_mask 1160.

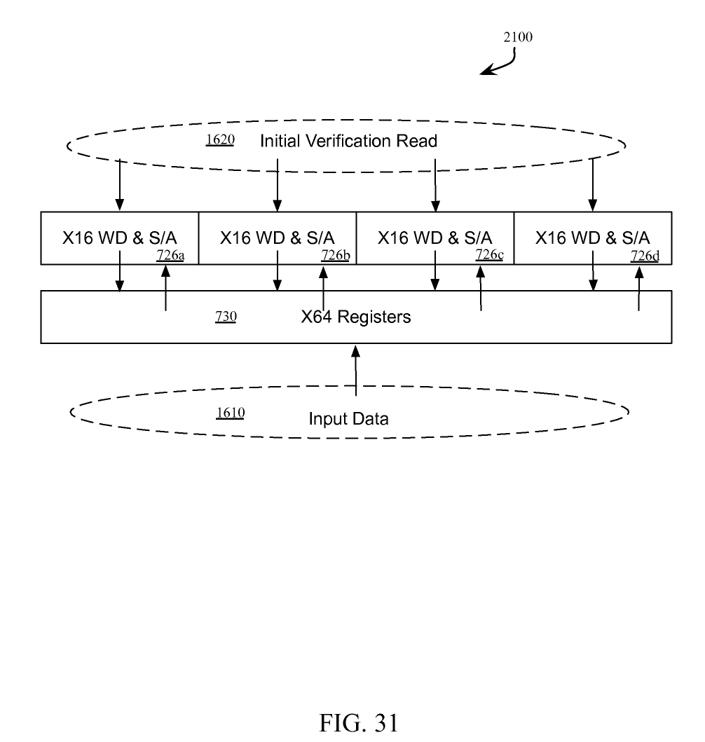

FIG. 31 shows the flow of data for performing the equivalence function in the register 730. The input data 1610 is held in the registers 730 and the verification read is held in block 726. The register 730 communicates a signal to the write driver (FIG. 21) indicating whether the input data 1610 and the sense amplifier output 1280 match or not. FIG. 32 further describes the logic states of the equivalence function (e.g. masking). When the data from the verification read 1620 matches the input data for write 1610, the Data_mask 1160 is one, thereby disabling NOR gates 1157 and 1158 (FIG. 21). The write driver output 1156 drives no current (e.g. tri-state or “X”). When the data from the verification read 1620 does not match the input data for write 1610, the Data_mask 1160 is zero, thereby enabling NOR gates 1157 and 1158 (FIG. 21). The write driver output 1156 drives a current determined by the state of the input data for write 1610 (e.g. a RESET current 1140 or a SET current 1142).

In the embodiments described above, the device elements and circuits may be connected directly to each other or alternatively may be indirectly connected to each other through other elements, circuits and the like without departing from the spirit or scope of the invention. Furthermore, alterations, modifications and variations within the knowledge of those skilled in the art are considered within the scope of the invention.

While the invention has been shown and described with reference to specific preferred embodiments, it should be understood by those skilled in the art that various changes in form and detail may be made therein without departing from the spirit and scope of the invention as defined by the following claims.

What is claimed is:

1. A method for writing a phase change memory comprising:
receiving an input data corresponding to a plurality of memory cells, while reading a previous data from the plurality of memory cells and comparing the input data with the previous data; and
upon determining that the input data is different from the previous data for one or more of the plurality of memory cells, and upon determining that a current value of a write counter is less than a maximum value, programming the one or more of the plurality of memory cells with the input data and incrementing the current value of the write counter.

2. The method of claim 1 wherein receiving an input data further comprises receiving a burst of the input data, the burst including a plurality of data-words.

3. The method of claim 2 wherein the burst of the input data is received with a single data rate (SDR), wherein each of the plurality of data-words is clocked on one clock edge.

4. The method of claim 2 wherein the burst of the input data is received with a double data rate (DDR), wherein each of the plurality of data-words is clocked on one of a rising and a falling clock edge.

5. The method of claim 1 wherein the input data is stored in a register, the previous data is stored in a sense amplifier, and comparing the input data with the previous data occurs in the sense amplifier with the comparison results communicated to a write driver.

6. The method of claim 1 wherein the input data is stored in a register, the previous data is stored in a sense amplifier, and comparing the input data with the previous data occurs in the register with the comparison results communicated to a write driver.

7. The method of claim 1 wherein the current value of the write counter is initially set to zero.

8. The method of claim 1 wherein a fail flag is set when the current value is equal to the maximum value.

9. An apparatus for writing a phase change memory comprising:
a sense amplifier including a bias transistor and a differential voltage amplifier, the bias transistor in communication with a positive input of a differential voltage amplifier, one of a plurality of memory cells in communication with the positive input of the differential voltage amplifier, a sense voltage at the positive input of the differential voltage amplifier being in proportion to a bias resistance of the bias transistor and a memory cell resistance of the one of the plurality of memory cells, a reference voltage in communication with a negative input of the differential voltage amplifier, the reference voltage being between the sense voltage obtained at the positive input of the differential voltage amplifier for the one of the plurality of memory cells in a SET state and the one of the plurality of memory cells in a RESET state;
a register retaining the state of a plurality of bits in a data-word;
a write driver having a write current branch, a reset current branch and a set current branch, the reset current branch enabled by a RESET state and disabled by a data-mask state, the set current branch enabled by a SET state and disabled by the data-mask state, the write current branch mirroring a current of one of the reset current branch and the set current branch; and
an equivalence circuit setting the data-mask state corresponding to a bit in the data-word having the SET state when a corresponding sensed bit in the plurality of memory cells has the SET state, and setting the data-mask state corresponding to a bit in the data-word having the RESET state when a corresponding sensed bit in the plurality of memory cells has the RESET state.

10. The apparatus of claim 9 wherein the equivalence circuit is an exclusive-NOR gate, the corresponding sensed bit in communication with one input of the exclusive-NOR gate, and the bit in the data-word in communication with another input of the exclusive-NOR gate.

11. The apparatus of claim 9 wherein the plurality of memory cells includes a phase change memory.

12. The apparatus of claim 9 wherein a first duration for the register to receive a burst of data-words substantially overlaps with a second duration for the sense amplifier to sense one of the plurality of memory cells and for the equivalence circuit to set the data-mask state.

13. The apparatus of claim 12 wherein the burst of the data-words includes eight data words.

14. A phase change memory system comprising:
a memory array including a plurality of memory cells, each of the plurality of memory cells located at one of a plurality of rows and at one of a plurality of columns;
a plurality of local column selectors, each local column selector being in communication with a plurality of columns;
a global column selector in communication with the plurality of local column selectors;
a sense amplifier in communication with the global column selector, the sense amplifier including a bias transistor and a differential voltage amplifier, the bias transistor in communication with a positive input of a differential voltage amplifier, one of a plurality of memory cells in communication with the positive input of the differential voltage amplifier, a sense voltage at the positive input of the differential voltage amplifier being in proportion to a bias resistance of the bias transistor and a memory cell resistance of the one of the plurality of memory cells, a reference voltage in communication with a negative input of the differential voltage amplifier, the reference voltage being between the sense voltage obtained at the positive input of the differential voltage amplifier for the one of the plurality of memory cells in a set state and the one of the plurality of memory cells in a reset state;
a register retaining the state of a plurality of bits in a data-word;
a write driver in communication with the global column selector, the write driver having a write current branch, a reset current branch and a set current branch, the reset current branch enabled by a reset state and disabled by a data-mask state, the set current branch enabled by a set state and disabled by the data-mask state, the write current branch mirroring a current of one of the reset current branch and the set current branch; and
an equivalence circuit setting the data-mask state corresponding to a bit in the data-word having the set state when a corresponding sensed bit in the plurality of memory cells has the set state, and setting the data-mask state corresponding to a bit in the data-word having the reset state when a corresponding sensed bit in the plurality of memory cells has the reset state.

15. The system of claim 14 wherein the equivalence circuit is an exclusive-NOR gate, the corresponding sensed bit in communication with one input of the exclusive-NOR gate, and the bit in the data word in communication with another input of the exclusive-NOR gate.

16. The system of claim 14 wherein the plurality of memory cells includes a phase change memory.

17. The system of claim 14 wherein a first duration for the register to receive a burst of data-words substantially overlaps with a second duration for the sense amplifier to sense one of the plurality of memory cells and for the equivalence circuit to set the data-mask state.

18. The system of claim 17 wherein the burst of the data-words includes eight data words.
